(19) United States
(12) Patent Application Publication
(10) Pub. No.: US 2019/0045658 A1
(43) Pub. Date: Feb. 7, 2019

(54) THERMAL TECHNOLOGIES INCORPORATING SUPER-ELASTIC MATERIALS

(71) Applicant: Intel Corporation, Santa Clara, CA (US)

(72) Inventors: David Pidwerbecki, Hillsboro, OR (US); Jerrod Peterson, Hillsboro, OR (US); Christopher Moore, Hillsboro, OR (US)

(21) Appl. No.: 15/859,396

(22) Filed: Dec. 30, 2017

(51) Int. Cl. H05K 7/20; F16F 1/02; H05K 1/02

(52) U.S. Cl. CPC H05K 7/2049; F16F 1/021; F16F 1/027; H05K 2201/066; H05K 7/20418; F16F 2224/0258; H05K 1/021

(57) ABSTRACT

Thermal exchanger securing devices, and compute resources that include one or more thermal exchanger securing devices, are disclosed herein. The thermal exchanger securing devices are used to secure a thermal exchanger to an integrated circuit package, and to secure a thermal exchanger and an integrated circuit package of a compute resource to a printed circuit board.

### BACKGROUND

Thermal solutions may be employed to dissipate heat generated by electronic devices during operation thereof. Physical loads may be applied to an electronic device at a thermal interface to facilitate conduction of heat from the electronic device to a heat sink. Management of the loads applied to the thermal interface can improve heat transfer from an electronic device to a heat sink, thereby improving the performance of the electronic device.

Management of physical loads applied to electronic devices at the thermal interfaces may be complicated by a number of various factors. Those factors may include manufacturing tolerances of assemblies used to apply the loading at the thermal interfaces, properties of materials used in those assemblies, and characteristics of materials that form the thermal interfaces, just to name a few. Designing thermal solutions that account for those factors while avoiding degradation of the electronic devices or the thermal interfaces remains an area of interest.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is a simplified diagrammatic view of at least one embodiment of a compute device that includes a printed circuit board and multiple compute resources affixed thereto;

FIG. 2 is a simplified diagrammatic view of one of the compute resources included in the compute device of FIG. 1;

FIG. 3 is a top view of a thermal exchanger securing device that may be used to secure a thermal exchanger and an integrated circuit package of the compute resource depicted in FIG. 2 to the printed circuit board;

FIG. 4 is a front elevation view of elastic deformers of the thermal exchanger securing device of FIG. 3 in un-deformed positions (shown in solid) and deformed positions (shown in phantom);

FIG. 5 is a perspective view of the compute resource of FIG. 2 with an integrated circuit package coupled to the printed circuit board, a thermal exchanger coupled to the integrated circuit package, and a pair of thermal exchanger securing devices coupled to the thermal exchanger such that the elastic deformers of each thermal exchanger securing device are in the un-deformed positions;

FIG. 6 is a perspective view of the compute resource of FIG. 5 with the elastic deformers of each thermal exchanger securing device in the deformed positions;

FIG. 7 is a simplified flowchart of at least one embodiment of a method for mounting the compute resource of FIG. 2 to a printed circuit board;

FIG. 8 is a graphical representation of pressures applied by the thermal exchanger securing devices of the illustrative compute resource of FIG. 6 during a simulated, low load condition;

FIG. 9 is a graphical representation similar to FIG. 8 of pressures applied by the illustrative thermal exchanger securing devices during a simulated, medium load condition;

FIG. 10 is a graphical representation similar to FIG. 8 of pressures applied by the illustrative thermal exchanger securing devices during a simulated, high load condition;

FIG. 11 is a graphical representation of bond line thicknesses of a thermal interface material when pressures are applied by the illustrative thermal exchanger securing devices of the compute resource during the simulated, low load condition of FIG. 8;

FIG. 12 is a graphical representation of bond line thicknesses of the thermal interface material when pressures are applied by the illustrative thermal exchanger securing devices of the compute resource during the simulated, medium load condition of FIG. 9;

FIG. 13 is a graphical representation of bond line thicknesses of the thermal interface material when pressures are applied by the illustrative thermal exchanger securing devices of the compute resource during the simulated, high load condition of FIG. 10;

FIG. 14 is a graphical representation of pressures applied during a simulated, low load condition by non-illustrative devices whose construction differs from that of the illustrative thermal exchanger securing devices of the compute resources;

FIG. 15 is a graphical representation similar to FIG. 14 of pressures applied by the non-illustrative devices during a simulated, medium load condition;

FIG. 16 is a graphical representation similar to FIG. 14 of pressures applied by the non-illustrative devices during a simulated, high load condition;

FIG. 17 is a graphical representation of bond line thicknesses of conductive material when pressures are applied by the non-illustrative devices during the simulated, low load condition of FIG. 14;

FIG. 18 is a graphical representation of bond line thicknesses of conductive material when pressures are applied by the non-illustrative devices during the simulated, medium load condition of FIG. 15; and

FIG. 19 is a graphical representation of bond line thicknesses of conductive material when pressures are applied by the non-illustrative devices during the simulated, high load condition of FIG. 16.

### DETAILED DESCRIPTION OF THE DRAWINGS

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

The disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features.

Referring now to FIG. 1, an illustrative compute device 100 includes a printed circuit board (PCB) 102 and multiple compute resources 104, 106 mounted to the PCB 102. The compute device 100 may be embodied as any type of compute device capable of performing various compute functions including, but not limited to a computer, a desktop computer, a mobile computer, a laptop computer, a tablet computer, a notebook, a netbook, an Ultrabook™, a smart device, a personal digital assistant, a mobile Internet device, a server, a router, a switch, a network compute device, and/or other compute device or other device having electronic circuitry included therein. The PCB 102 may be formed from an FR-4 material or the like.

Each of the compute resources 104, 106 may be embodied as any type of compute resource that generates heat during operation and may include, for example, a processor, integrated circuit package, or other electrical component as discussed in more detail below. As such, the compute resources 104, 106 may be similar or different types of compute resources. Although only the two compute resources 104, 106 are shown in FIG. 1, it should be appreciated that the compute device 100 may include additional compute resources in other embodiments, which may be similarly mounted to the PCB 102. As discussed in greater detail below, the compute resources 104, 106 include one or more respective thermal exchanger securing devices 108, 110 that are used to secure components of the compute resources 104, 106 to the PCB 102. In doing so, the thermal exchanger securing devices 108, 110 facilitate dissipation of heat generated by components of the respective compute resources 104, 106 during operation thereof to improve performance of those components.

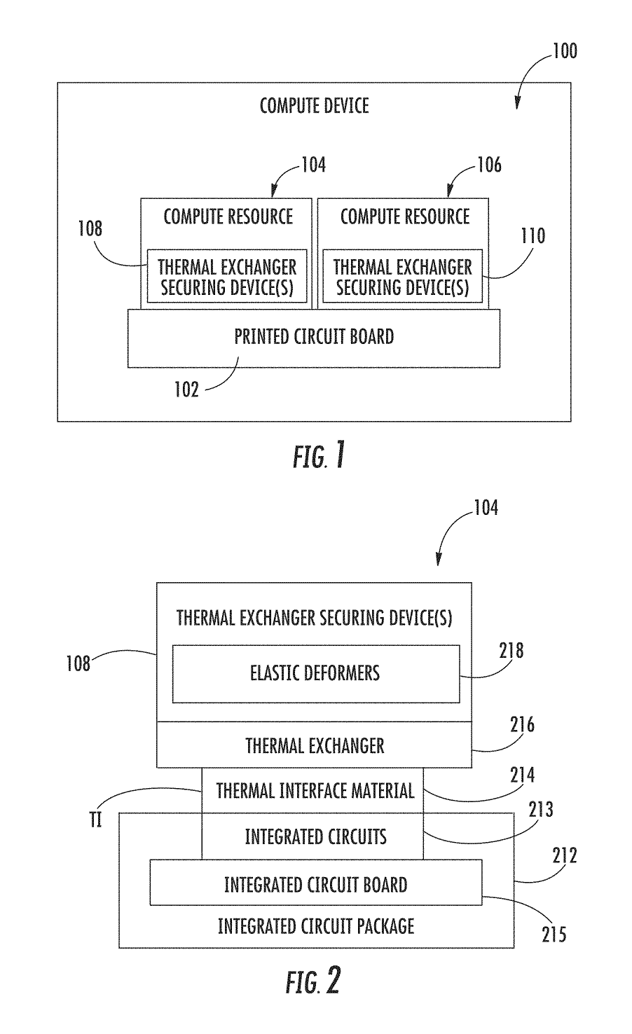

Referring now to FIG. 2, the illustrative compute resource 104 includes, in addition to the one or more thermal exchanger securing devices 108, an integrated circuit package 212, a thermal interface material 214, and a thermal exchanger 216. Each thermal exchanger securing device 108 includes one or more elastic deformers 218. In the illustrative arrangement of the compute resource 104, the integrated circuit package 212 is affixed to the PCB 102, and the thermal interface material 214 is arranged intermediate the integrated circuit package 212 and the thermal exchanger 216 to form a thermal interface TI therebetween. As further discussed below, the elastic deformers 218 are attached to the PCB 102 to secure the thermal exchanger 216 and the integrated circuit package 212 to the PCB 102 using the one or more thermal exchanger securing devices 108. During operation of the illustrative compute resource 104, heat generated by the integrated circuit package 212 is conducted via the thermal interface material 214 to the thermal exchanger 216 for dissipation by the thermal exchanger 216. The conductivity of the thermal interface material 214 depends, at least in part, on the thickness of the thermal interface material 214. The magnitude and uniformity of the thickness is dependent upon the mechanical load applied to the thermal interface material 214 by the thermal exchanger securing device 108.

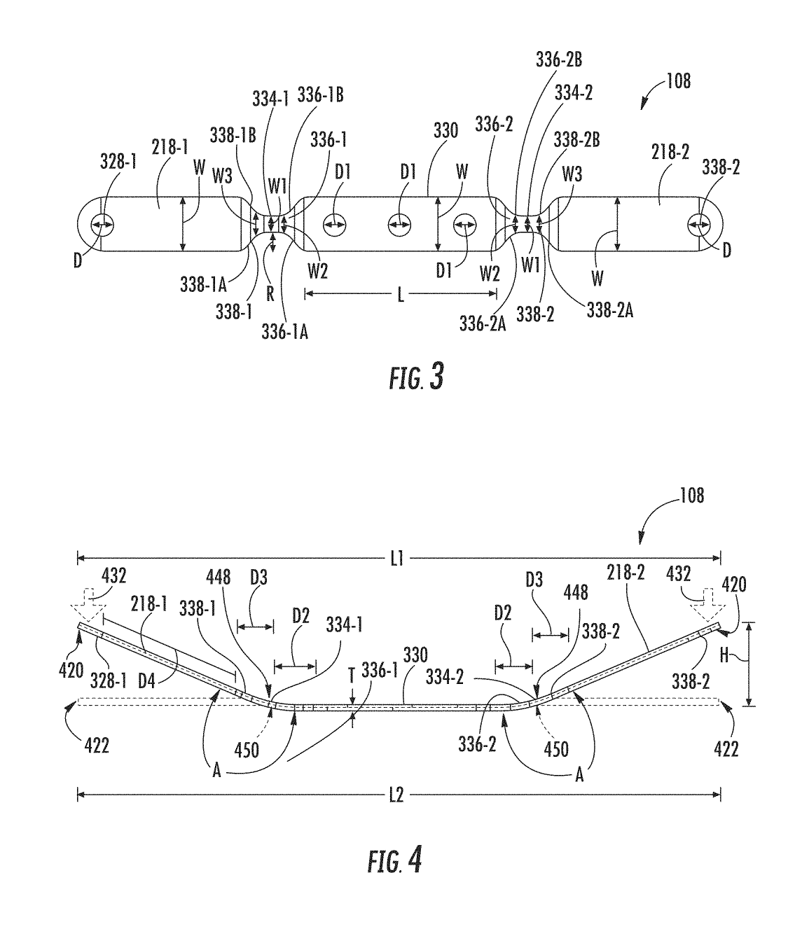

In the illustrative embodiment, each of the elastic deformers 218 of each thermal exchanger securing device 108 is moveable from an un-deformed or un-deflected position 420 (see FIG. 4) to a deformed or deflected position 422 (see FIG. 4). In the un-deformed position 420, mounting apertures 328 (see FIG. 3) formed in each elastic deformer 218 are spaced from the PCB 102 such that each thermal exchanger securing device 108, as well as the thermal exchanger 216, are not secured to the PCB 102. Consequently, a minimal mechanical load is applied to the thermal interface material 214, the thermal exchanger 216, and the integrated circuit package 212 by each thermal exchanger securing device 108 when the elastic deformers 218 are in the un-deformed position 420. In the deformed position 422, the mounting apertures 328 are arranged in close proximity to the PCB 102 to facilitate securement of each thermal exchanger securing device 108, as well as the thermal exchanger 216, to the PCB 102 via each mounting aperture 328. As a result, a non-minimal mechanical load is applied to the thermal interface material 214, the thermal exchanger 216, and the integrated circuit package 212 by each thermal exchanger securing device 108 when the elastic deformers 218 are secured to the PCB 102 in the deformed position 422.

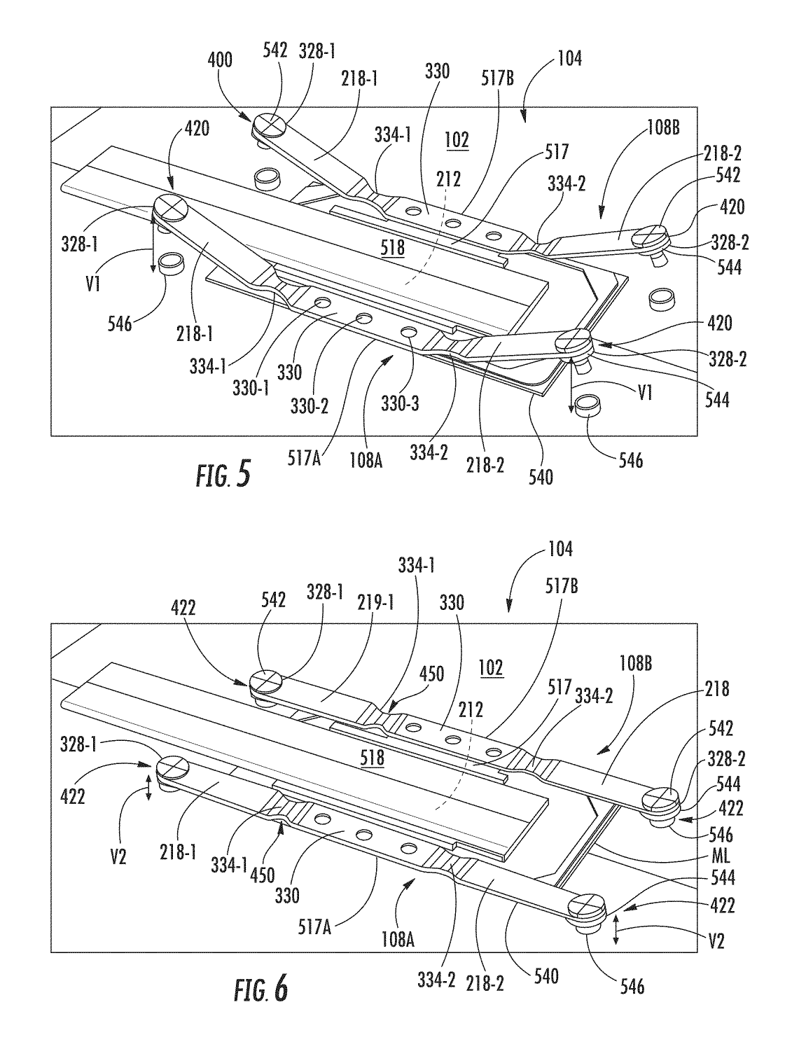

In the illustrative embodiment, the elastic deformers 218 of each thermal exchanger securing device 108 extend from a main body 330 (see FIG. 3). The main body 330 is formed to couple with the thermal exchanger 216, as discussed below with reference to FIG. 5. The main body 330 and the elastic deformers 218 of each thermal exchanger securing device 108 are each formed from a super-elastic material. In combination with other features of each thermal exchanger securing device 108, the illustrative construction of each thermal exchanger securing device 108 provides advantages not achieved by other configurations, as further discussed below.

Referring again to FIG. 2, the illustrative integrated circuit package 212 may include, or otherwise embodied as, any device having electronic circuitry that generates heat during operation thereof and is capable of being affixed to the PCB 102. In the illustrative embodiment, the integrated circuit package 212 includes one or more integrated circuits 213 that are mounted to an integrated circuit board 215. Each of the integrated circuits 213 may be embodied as, or otherwise include, a processor, a co-processor, a microprocessor, an accelerator, a field programmable gate arrays (FPGAs), a memory device, a data storage device, a power electronic device, gating circuitry, a control circuit, a network interface controller, and/or other electronic device, electronic circuit, or the like. Each of the integrated circuits 213 may be mounted to the integrated circuit board 215 via one or more solder balls (not shown). The integrated circuit board 215 may be formed from FR-4 material or the like.

The illustrative thermal interface material 214 may be embodied as any type of material that is capable of providing a thermal coupling between the thermal exchanger 216 and the integrated circuit package 212 to conduct heat generated by the integrated circuit package 212 to the thermal exchanger 216 during operation of the compute resource 104. For example, in the illustrative embodiment, the thermal interface material 214 is embodied as thermal grease. Of course, it should be appreciated that in other embodiments, the thermal interface material 214 may be embodied as other types of thermal interface materials including, but not limited to thermal glue, thermal gap filler, a thermal pad, a thermal adhesive, or the like.

The illustrative thermal exchanger 216 may be embodied as any device, or collection of devices, capable of transferring away heat produced by the integrated circuit package 212 to dissipate the heat during operation of the compute resource 104. For example, in the illustrative embodiment, the thermal exchanger 216 includes, or is otherwise embodied as, a cold plate 517 and a conduit 518 (see FIG. 5). The conduit 518 may include, or otherwise be embodied as, one or more heat pipes, vapor chambers, metal strips, graphite strips, or any other components formed from thermally conductive material. Of course, it should be appreciated that in other embodiments, the thermal exchanger 216 may include, or otherwise be embodied as, another suitable device or collection of devices. In such embodiments, the thermal exchanger 216 may include, or otherwise be embodied as, a shell and tube heat exchanger, a plate heat exchanger, a plate and shell heat exchanger, a plate fin heat exchanger, a pillow plate heat exchanger, a microchannel heat exchanger, a waste recovery unit, a helical-coil heat exchanger, a spiral heat exchanger, or the like, for example.

Referring now to FIG. 3, each thermal exchanger securing device 108 (only one of which is shown) is formed such that after the elastic deformers 218 move from the un-deformed position 420 toward the deformed position 422 in response to a mounting forces 432 (see FIG. 4) that are applied to each elastic deformer 218, each of the elastic deformers 218 is configured to move back substantially to the un-deformed position 420, such as when the mounting forces 432 are removed and/or when heat is applied to each elastic deformer 218, for example. Put differently, each elastic deformer 218 is formed to elastically (i.e., recoverably) deform such that movement of each elastic deformer 218 from the deformed position 422 to the un-deformed position 420 is facilitated when each thermal exchanger securing device 108 is not secured to the PCB 102 via the mounting apertures 328.

As discussed above, the thermal exchanger securing device 108 is illustratively formed from a super-elastic material, which may include a shape-memory alloy or another material that exhibits super-elastic behavior. For example, in the illustrative embodiment, the main body 330 and the elastic deformers 218 of each thermal exchanger securing device 108 are formed from Nickel-Titanium (also known as “Nitinol”). Compared to other configurations, and in combination with other structural features of each thermal exchanger securing device 108, the illustrative Nitinol construction of each thermal exchanger securing device 108 provides a number of benefits relative to typical securing devices. In one respect, the construction of each thermal exchanger securing device 108 enables each elastic deformer 218 to deform to a significantly greater degree (i.e., to experience greater strain) in response to mounting forces 432 applied thereto, and the resulting internal stresses that are generated, than would be the case if each thermal exchanger securing device 108 had a different construction, such as a high-strength steel construction, for example. In another respect, each thermal exchanger securing device 108 has a significantly lower stiffness, and deforms more in response to being subjected to stresses increasing above a certain threshold, than would be the case if each thermal exchanger securing device 108 had a high-strength steel construction. As a result, the Nitinol construction, which may be said to impart super-elastic properties to each thermal exchanger securing device 108, improves the ability of each elastic deformer 218 to withstand stresses above that threshold over the lifecycle of the compute resource 104, which may reduce the risk of degrading one or more components of the compute resource 104. In yet another respect, the stiffness of each thermal exchanger securing device 108 enables decreased sensitivity to deformation variations in the elastic deformers 218 that may accumulate due to manufacturing tolerances of various components of the compute resource 104, such as the thermal exchanger securing device 108, the integrated circuit package 212, and the PCB 102, at least in comparison to other configurations. In view of that reduced sensitivity, the illustrative construction of each thermal exchanger securing device 108 may improve the ability of the device 108 to meet and manage design objectives for mechanical forces and pressures applied to components of the compute resource 104, which may improve the performance of the thermal exchanger 216 compared to other configurations, as well as provide other advantages.

In the illustrative embodiment, each thermal exchanger securing device 108 may be embodied as any type of device capable of storing mechanical energy and interfacing with the thermal exchanger 216 and the PCB 102 to secure the thermal exchanger 216 and the integrated circuit package 212 to the PCB 102 when the device is in a deformed position (e.g., the deformed position 422). For example, in the illustrative embodiment of FIGS. 3 and 4, each thermal exchanger securing device 108 is embodied a leaf spring. However, it should be appreciated that in other embodiments, each thermal exchanger securing device 108 may include, or otherwise be embodied as, another suitable device such as a tension spring, a compression spring, a torsion spring, a wave spring, a Belleville washer, a bar, a frame, or the like, for example.

In the illustrative embodiment, each thermal exchanger securing device 108 includes two elastic deformers 218-1, 218-2 that are coupled to, and extend from, the main body 330. A neck 334-1 is coupled between the elastic deformer 218-1 and the main body 330, and a neck 334-2 is coupled between the elastic deformer 218-2 and the main body 330. Mounting apertures 328-1, 328-2 are formed in the respective elastic deformers 218-1, 218-2. The main body 330 is formed to include apertures 330-1, 330-2, and 330-3.

In the illustrative embodiment, the main body 330 and the elastic deformers 218-1, 218-2 of each thermal exchanger securing device 108 have substantially the same width W, which is about 5.00 millimeters. The necks 334-1, 334-2 each have a width W1 of about 2.10 millimeters. The mounting apertures 328-1, 328-2 each have a diameter D of about 2.30 millimeters, whereas the apertures 330-1, 330-2, 330-3 each have a diameter D1 of about 2.00 millimeters. Additionally, the main body 330 has a length L of about at least 18.00 millimeters.

Each illustrative thermal exchanger securing device 108 includes neck-body transition segments 336-1, 336-2 and neck-deformer transition segments 338-1, 338-2. The neck-body transition segment 336-1 interconnects the main body 330 with the neck 334-1, and the neck-deformer transition segment 338-1 interconnects the neck 334-1 with the elastic deformer 218-1. Similarly, the neck-body transition segment 336-2 interconnects the main body 330 with the neck 334-2, and the neck-deformer transition segment 338-2 interconnects the neck 334-2 with the elastic deformer 218-2. Each neck-body transition segment 336-1, 336-2 has a width W2 that is greater than the width W1 of the necks 334-1, 334-2 and less than the width W of the main body 330 and the elastic deformers 218-1, 218-2. Additionally, each neck-deformer transition segment 338-1, 338-2 has a width W3 that is greater than the width W1 of the necks 334-1, 334-2 and less than the width W of the main body 330 and the elastic deformers 218-1, 218-2.

In the illustrative embodiment, the neck-body transition segment 336-1 is partially defined by arcs 336-1A, 336-1B that are arranged opposite one another, and the neck-deformer transition segment 338-1 is partially defined by arcs 338-1A, 338-1B that are arranged opposite one another. Similarly, the neck-body transition segment 336-2 is partially defined by arcs 336-2A, 336-2B that are arranged opposite one another, and the neck-deformer transition segment 338-2 is partially defined by arcs 338-2A, 338-2B that are arranged opposite one another. Each of the arcs 336-1A, 336-1B, 336-2A, 336-2B, 338-1A, 338-1B, 338-2A, 338-2B illustratively has substantially the same radius R, which is about 3.00 millimeters.

Referring now to FIG. 4, in the illustrative embodiment, each thermal exchanger securing device 108 has a uniform thickness T of about 0.60 millimeters. Prior to application of the mounting forces 432 to the elastic deformers 218-1, 218-2 to cause the elastic deformers 218-1, 218-2 to move from the un-deformed position 420 toward the deformed position 422, each thermal exchanger securing device 108 illustratively extends over a length L1 of about 65.87 millimeters and has a height H in the range of about 8.67 millimeters to 9.47 millimeters. When each of the elastic deformers 218-1, 218-2 is moved to the deformed position 422, each elastic each thermal exchanger securing device 108 illustratively extends over a length L2 of about 68.99 millimeters.

In the illustrative embodiment, the elastic deformers 218-1, 218-2 extend outwardly from the main body 330 of each thermal exchanger securing device 108 at obtuse angles measured from the main body 330 when the elastic deformers 218-1, 218-2 are in the un-deformed position 420. Specifically, each of the elastic deformers 218-1, 218-2 extends outwardly from the main body 330 at an angle A of about 203.6° measured from the main body 330 when the elastic deformers 218-1, 218-2 are in the un-deformed position 420.

When the elastic deformers 218-1, 218-2 are in the un-deformed position 420 such that each of the elastic deformers 218-1, 218-2 extends outwardly from the main body 330 at the angle A of about 203.6° measured from the main body 330, the necks 334-1, 334-2 are illustratively in an un-flexed position 448. When the elastic deformers 218-1, 218-2 move from the un-deformed position 420 to the deformed position 422 such that the elastic deformers 218-1, 218-2 extend generally parallel to the main body 330 as shown in FIG. 4, the necks 334-1, 334-2 move from the un-flexed position 448 to an illustrative flexed position 450. In the illustrative embodiment, movement of the necks 334-1, 334-2 from the un-flexed position 448 to the flexed position 450 may be accompanied by some movement of the neck-body transition segments 336-1, 336-2 and the neck-deformer transition segments 338-1, 338-2. In cooperation with movement of the neck-body transition segments 336-1, 336-2 and the neck-deformer transition segments 338-1, 338-2, movement of the necks 334-1, 334-2 from the un-flexed position 448 to the flexed position 450 may facilitate movement of the elastic deformers 218-1, 218-2 from the un-deformed position 420 to the deformed position 422.

In the illustrative embodiment, the main body 330 is spaced from the necks 334-1, 334-2 by a distance D2 of about 3.91 millimeters when the elastic deformers 218-1, 218-2 are in the un-deformed position 420. The necks 334-1, 334-2 are spaced from the elastic deformers 218-1, 218-2, respectively, by a distance D3 of about 3.92 millimeters when the elastic deformers 218-1, 218-2 are in the un-deformed position 420. When the elastic deformers 218-1, 218-2 are in the un-deformed position 420, a distance D4 measured parallel to the respective elastic deformers 218-1, 218-2 from the neck-deformer transition segments 338-1, 338-2 to the center of the mounting apertures 328-1, 328-2 is about 14.80 millimeters.

Referring now to FIGS. 5 and 6, the illustrative compute resource 104 includes two substantially identical thermal exchanger securing devices 108A, 108B, which are illustratively used to secure the thermal exchanger 216 and the integrated circuit package 212 to the PCB 102. Of course, it should be appreciated that in other embodiments, the compute resource 104 may include another suitable number of thermal exchanger securing devices 108.

In the illustrative embodiment, a backing plate 540 is arranged between the PCB 102 and the integrated circuit package 212. However, it should be appreciated that in other embodiments, the backing plate 540 may be omitted such that the integrated circuit package 212 is in direct contact with the PCB 102. In any case, the thermal interface material 214 is applied to one or more of the integrated circuit package 212 and the cold plate 517 of the thermal exchanger 216 such that the thermal interface material 214 is arranged between the integrated circuit package 212 and the cold plate 517. The conduit 518 of the thermal exchanger 216 is arranged in contact with the cold plate 517 such that the conduit 518 is arranged above the cold plate 517 relative to the PCB 102. In the illustrative arrangement of FIGS. 5 and 6, the main body 330 of the thermal exchanger securing device 108A couples with the cold plate 517 along a side 517A thereof, and the main body 330 of the thermal exchanger securing device 108B couples with the cold plate along a side 517B thereof that is arranged opposite the side 517A. In some embodiments, the main body 330 of the thermal exchanger securing device 108A may be attached to the cold plate 517 by fasteners (not shown) that are inserted into the apertures 330-1, 330-2, 330-3, and the main body 330 of the thermal exchanger securing device 108B may be attached to the cold plate 517 by fasteners (not shown) that are inserted into the apertures 330-1, 330-2, 330-3.

The mounting apertures 328-1, 328-2 of each thermal exchanger securing device 108A, 108B are each sized to receive a fastener 542. When the fasteners 542 are received by the mounting apertures 328-1, 328-2, each of the fasteners 542 may be received by a washer 544. Additionally, when the fasteners 542 are received by the mounting apertures 328-1, 328-2, mounting forces 432 (see FIG. 4) applied to the elastic deformers 218-1, 218-2 of each thermal exchanger securing device 108A, 108B cause the elastic deformers 218-1, 218-2 and the fasteners 542 to move toward the PCB 102.

In the un-deformed position 420 of the elastic deformers 218-1, 218-2 shown in FIG. 5, the mounting apertures 328-1, 328-2 are spaced a vertical distance V1 from the PCB 102. Accordingly, when the elastic deformers 218-1, 218-2 are in the un-deformed position 420, the fasteners 542 received by the mounting apertures 328-1, 328-2 are spaced from bosses 546 that are in contact with the PCB 102 and sized to receive the fasteners 542. In contrast, in the deformed position 422 of the elastic deformers 218-1, 218-2 shown in FIG. 6, the mounting apertures 328-1, 328-2 are spaced a vertical distance V2 from the PCB 102 that is less than the vertical distance V1. When the elastic deformers 218-1, 218-2 are in the deformed position 422, the fasteners 542 may be received by the bosses 546 to secure the thermal exchanger 216 and the integrated circuit package 212 to the PCB 102 using the thermal exchanger securing devices 108A, 108B.

Referring now to FIG. 7, an illustrative method 700 of mounting the compute resource 104 to the PCB 102 is shown. The method begins with block 702 in which a determination regarding whether the compute resource 104 is to be mounted to the PCB 102 is made. If it is determined that the compute resource 104 is to be mounted to the PCB 102, the method 700 proceeds to block 704. In block 704, the compute resource 104 is arranged on the PCB 102 at a particular mounting location ML (see FIG. 6). In some embodiments, the integrated circuit package 212 is arranged on the PCB 102 at the mounting location ML. Regardless, subsequent to block 704, the method 700 proceeds to block 706.

In block 706, the thermal interface material 214 is applied to the integrated circuit package 212 of the compute resource 104. In some embodiments, in addition to applying the thermal interface material 214 to the integrated circuit package 212 in block 706, block 706 may optionally include the block 708 in which the thermal interface material 214 may be applied to the thermal exchanger 216 of the compute resource 104. In any case, the method 700 proceeds to block 710 subsequent to block 706.

In block 710, the thermal exchanger 216 of the compute resource 104 is mounted onto the integrated circuit package 212 of the compute resource 104. To do so, in block 712, the thermal exchanger 216 is arranged in contact with the thermal interface material 214 that is applied to the integrated circuit package 212 (i.e., in block 706). Subsequent to block 710, the method 700 proceeds to block 714.

In block 714, the compute resource 104 is secured to the PCB 102. To do so, blocks 716 and 718 are performed. In block 716, the thermal exchanger securing devices 108A, 108B are coupled to the thermal exchanger 216. For example, in block 716, the main body 330 of each thermal exchanger securing device 108A, 108B are coupled with the cold plate 517 along the respective sides 517A, 517B, as described above with reference to FIGS. 5 and 6. In that example, the elastic deformers 218-1, 218-2 of each thermal exchanger securing device 108A, 108B are in the un-deformed position 420 when the main body 330 of each thermal exchanger securing device 108A, 108B is coupled with the cold plate 517. In any case, subsequent to block 716, the thermal exchanger securing devices 108A, 108B are secured to the PCB 102 in block 718. To perform block 718, in block 720, the elastic deformers 218-1, 218-2 of each thermal exchanger securing device 108A, 108B are deformed and attached to the PCB 102 using the fasteners 542. To perform block 720, in block 722, the elastic deformers 218-1, 218-2 of each thermal exchanger securing device 108A, 108B are bent relative to the main body 330 of each thermal exchanger securing device 108A, 108B to cause the elastic deformers 218-1, 218-2 to move from the un-deformed position 420 to the deformed position 422. In some embodiments, block 722 may optionally include the block 724 in which the necks 334-1, 334-2 of each of the thermal exchanger securing devices 108A, 108B are moved from the un-flexed position 448 to the flexed position 450.

Referring back to block 702, if it is determined in block 702 that the compute resource 104 is not to be mounted to the PCB 102, another iteration of the method 700 may be performed beginning with block 702. Of course, it should be appreciated that the method 700 may be performed in a number of sequences other than the illustrative sequence of FIG. 7.

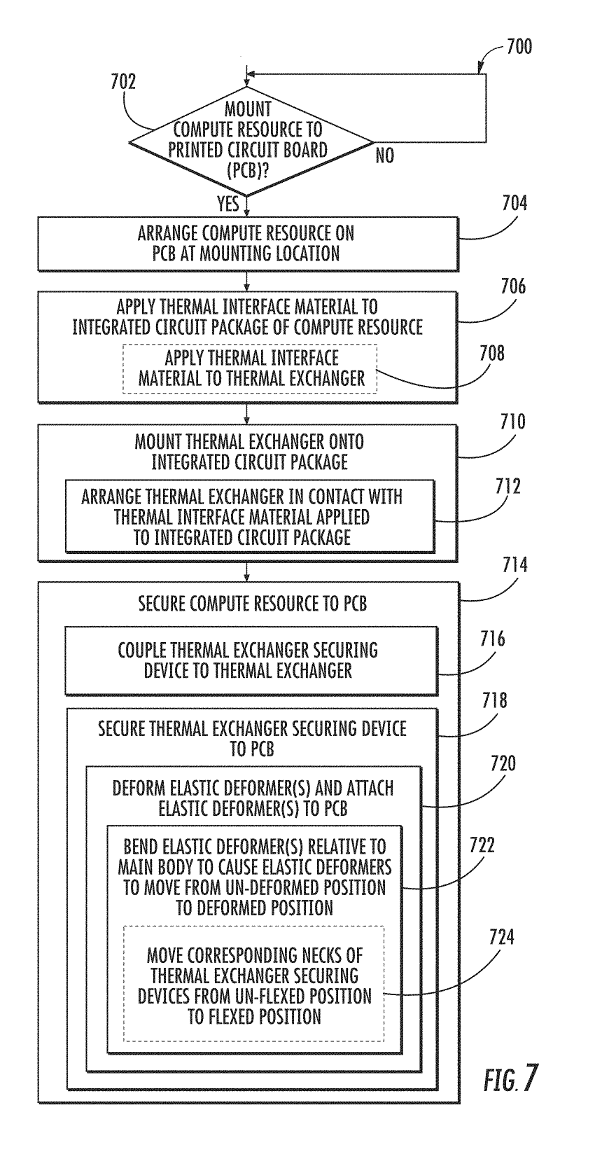

Referring now to FIGS. 8-10, pressures applied by the illustrative thermal exchanger securing devices 108A, 108B of the compute resource 104 when the compute resource 104 is secured to the PCB 102 (i.e., when the elastic deformers 218-1, 218-2 of each thermal exchanger securing device 108A, 108B are moved to the deformed positions 422), and loads associated therewith, are depicted during several conditions. The pressures (which may be referred to as die pressures) are applied to the integrated circuit package 212 in each of the conditions, and the loads (which may be referred to as total die loads) are experienced by the integrated circuit package 212 in each of the depicted conditions. Of course, it should be appreciated that the pressures may be applied to, and the loads associated therewith experienced by, one or more components of the compute resource 104 when the compute resource 104 is secured to the PCB 102 as discussed above, such as the thermal interface material 214, for example. In any case, each of the conditions depicted below assumes a displacement or deformation tolerance associated with the illustrative thermal exchanger securing devices 108A, 108B during operation thereof that is about ±0.65 millimeters. Additionally, each of the conditions depicted below assumes that the illustrative thermal exchanger securing devices 108A, 108B are designed to have a stiffness of about 0.80 N/mm to achieve a target displacement of about 8 millimeters during operation thereof.

As shown in FIG. 8, a low or minimum load condition 800 is associated with, or otherwise corresponds to, a displacement or deformation of the elastic deformers 218-1, 218-2 of the illustrative thermal exchanger securing devices 108A, 108B (e.g., a displacement measured from the un-deformed position 420) that is about 7.5 millimeters. In response to such deformation, the illustrative thermal exchanger securing devices 108A, 108B apply relatively low pressures to the integrated circuit package 212, and the integrated circuit package 212 experiences relatively low loads as a result. A maximum pressure 802 of about 32 psi is applied to the integrated circuit package 212 by the illustrative thermal exchanger securing devices 108A, 108B in the low load condition 800, and the integrated circuit package 212 experiences a total die load of about 6.4 lbf as a result.

As shown in FIG. 9, a medium or nominal load condition 900 is associated with, or otherwise corresponds to, a displacement or deformation of the elastic deformers 218-1, 218-2 of the illustrative thermal exchanger securing devices 108A, 108B (e.g., a displacement measured from the un-deformed position 420) that is about 8.1 millimeters. In response to such deformation, the illustrative thermal exchanger securing devices 108A, 108B apply pressures to the integrated circuit package 212 that are greater than those applied in the low load condition 800, and the integrated circuit package 212 experiences greater loads in the medium load condition 900 than in the low load condition 800 as a result. A maximum pressure 902 of about 42 psi is applied to the integrated circuit package 212 by the illustrative thermal exchanger securing devices 108A, 108B in the medium load condition 900, and the integrated circuit package 212 experiences a total die load of about 7.2 lbf as a result.

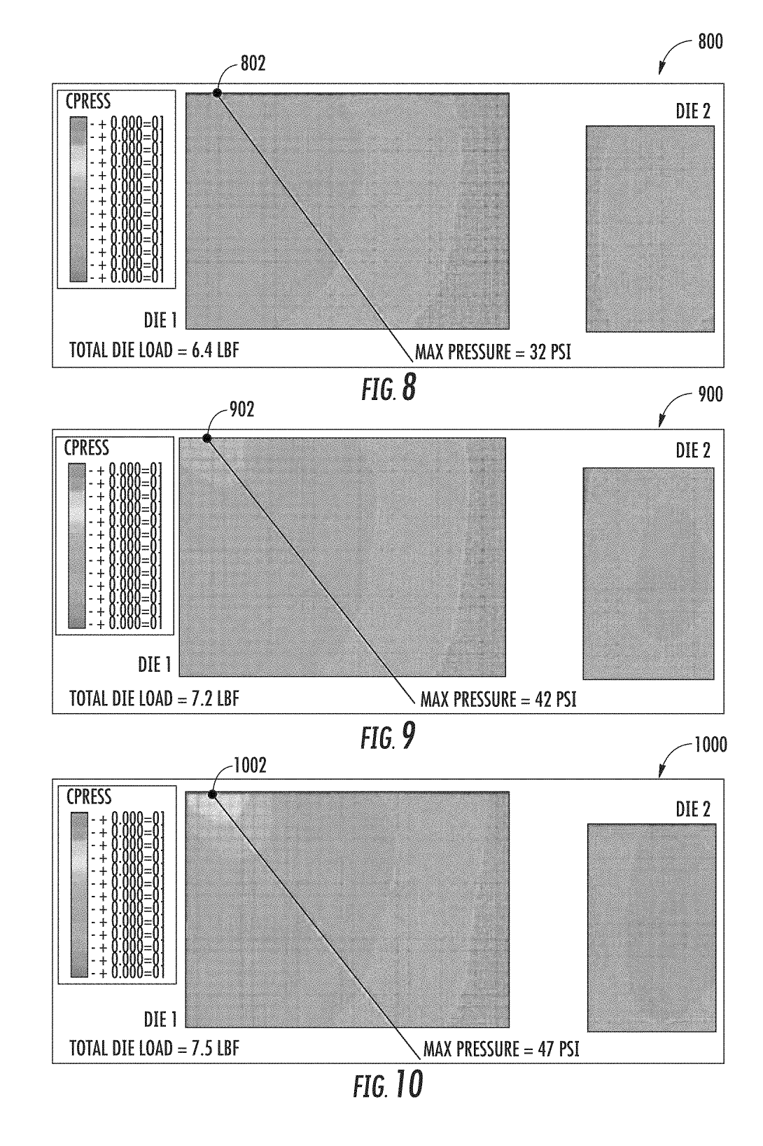

As shown in FIG. 10, a high or maximum load condition 1000 is associated with, or otherwise corresponds to, a displacement or deformation of the elastic deformers 218-1, 218-2 of the illustrative thermal exchanger securing devices 108A, 108B (e.g., a displacement measured from the un-deformed position 420) that is about 8.8 millimeters. In response to such deformation, the illustrative thermal exchanger securing devices 108A, 108B apply pressures to the integrated circuit package 212 that are greater than those applied in the medium load condition 900, and the integrated circuit package 212 experiences greater loads in the high load condition 1000 than in the medium load condition 900 as a result. A maximum pressure 1002 of about 47 psi is applied to the integrated circuit package 212 by the illustrative thermal exchanger securing devices 108A, 108B in the high load condition 1000, and the integrated circuit package 212 experiences a total die load of about 7.5 lbf as a result.

Referring now to FIGS. 11-13, bond line thicknesses of the thermal interface material 214 when the illustrative compute resource 104 is secured to the PCB 102 (i.e., when the elastic deformers 218-1, 218-2 of each thermal exchanger securing device 108A, 108B are moved to the deformed positions 422) are depicted during several conditions. The assumptions described above with reference to FIGS. 8-10 apply with equal force to FIGS. 11-13.

In response to the pressures applied by the illustrative thermal exchanger securing devices 108A, 108B during the low load condition 800, the bond line thicknesses of the thermal interface material 214 vary according to the bond line thickness map 1100 shown in FIG. 11. The bond line thickness map 1100 includes a point 1102 and a point 1104. The point 1102 is associated with, or otherwise corresponds to, a minimum bond line thickness of about 24 micrometers. The point 1104 is associated with, or otherwise corresponds to, a maximum bond line thickness of about 68 micrometers. The average bond line thickness indicated by the bond line thickness map 1100 is about 38 micrometers.

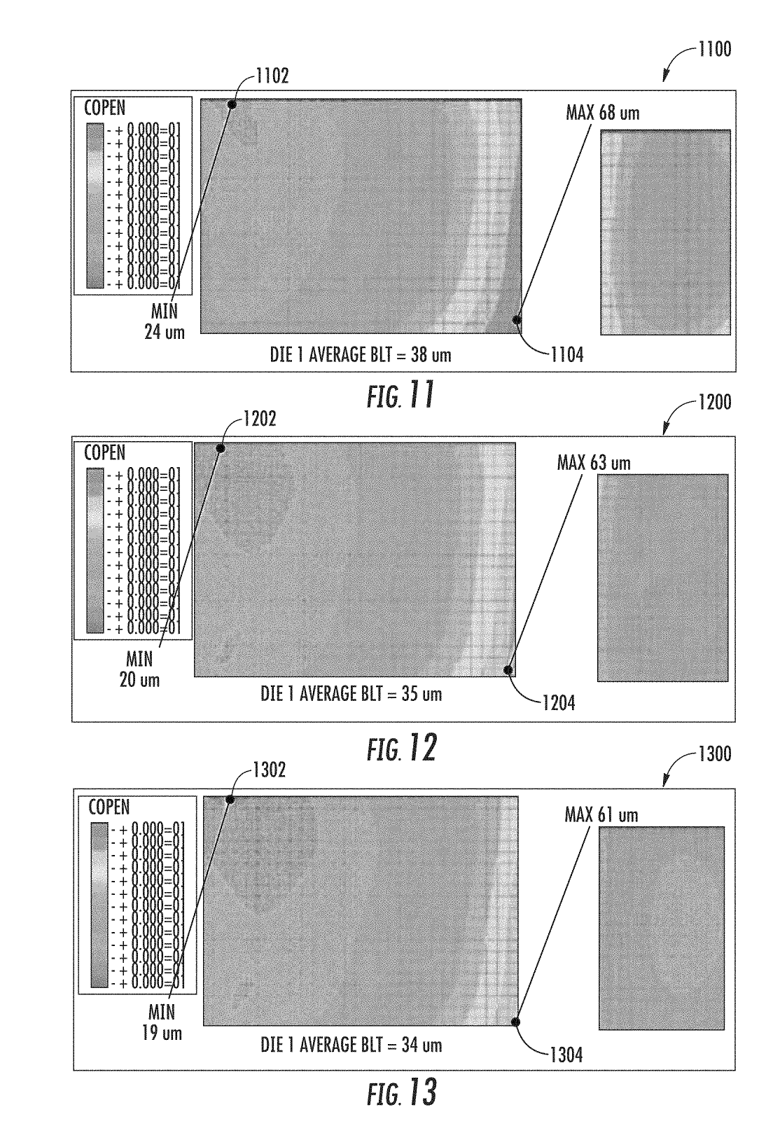

In response to the pressures applied by the illustrative thermal exchanger securing devices 108A, 108B during the medium load condition 900, the bond line thicknesses of the thermal interface material 214 vary according to the bond line thickness map 1200 shown in FIG. 12. The bond line thickness map 1200 includes a point 1202 and a point 1204. The point 1202 is associated with, or otherwise corresponds to, a minimum bond line thickness of about 20 micrometers. The point 1204 is associated with, or otherwise corresponds to, a maximum bond line thickness of about 63 micrometers. The average bond line thickness indicated by the bond line thickness map 1200 is about 35 micrometers.

In response to the pressures applied by the illustrative thermal exchanger securing devices 108A, 108B during the high load condition 1000, the bond line thicknesses of the thermal interface material 214 vary according to the bond line thickness map 1300 shown in FIG. 13. The bond line thickness map 1300 includes a point 1302 and a point 1304. The point 1302 is associated with, or otherwise corresponds to, a minimum bond line thickness of about 19 micrometers. The point 1304 is associated with, or otherwise corresponds to, a maximum bond line thickness of about 61 micrometers. The average bond line thickness indicated by the bond line thickness map 1300 is about 34 micrometers.

Referring now to FIGS. 8-13, across the low, medium, and high load conditions 800, 900, 1000 discussed above, the largest variation between the corresponding maximum pressures 802, 902, 1002 is about 15 psi. Additionally, the largest variation between the average bond thicknesses indicated by the bond thickness maps 1100, 1200, 1300, which correspond to the low, medium, and high load conditions 800, 900, 1000 discussed above, is 4 micrometers.

Referring now to FIGS. 14-16, pressures applied by securing devices (not shown) when the devices are employed in a fashion similar to the illustrative devices 108A, 108B, and loads associated therewith, are depicted during several conditions. The securing devices illustratively have a steel construction. Each of the conditions depicted below assumes a displacement or deformation tolerance associated with the securing devices during operation thereof that is about ±0.30 millimeters. Additionally, each of the conditions depicted below assumes that the securing devices are designed to have a stiffness of about 3.10 N/mm to achieve a target displacement of about 1 millimeter during operation thereof.

As shown in FIG. 14, a low or minimum load condition 1400 is associated with, or otherwise corresponds to, a displacement or deformation of the securing devices that is about 0.70 millimeters. In response to such deformation, the securing devices apply relatively low pressures and cause relatively low loads to be experienced as a result. A maximum pressure 1402 of about 19 psi is applied by the securing devices in the low load condition 1400, and a total die load of about 5.3 lbf is experienced as a result.

As shown in FIG. 15, a medium or nominal load condition 1500 is associated with, or otherwise corresponds to, a displacement or deformation of the securing devices that is about 1.00 millimeter. In response to such deformation, the securing devices apply pressures that are greater than those applied in the low load condition 1400, and greater loads are experienced in the medium load condition 1500 than in the low load condition 1400 as a result. A maximum pressure 1502 of about 29 psi is applied by the securing devices in the medium load condition 1500, and a total die load of about 7.3 lbf is experienced as a result.

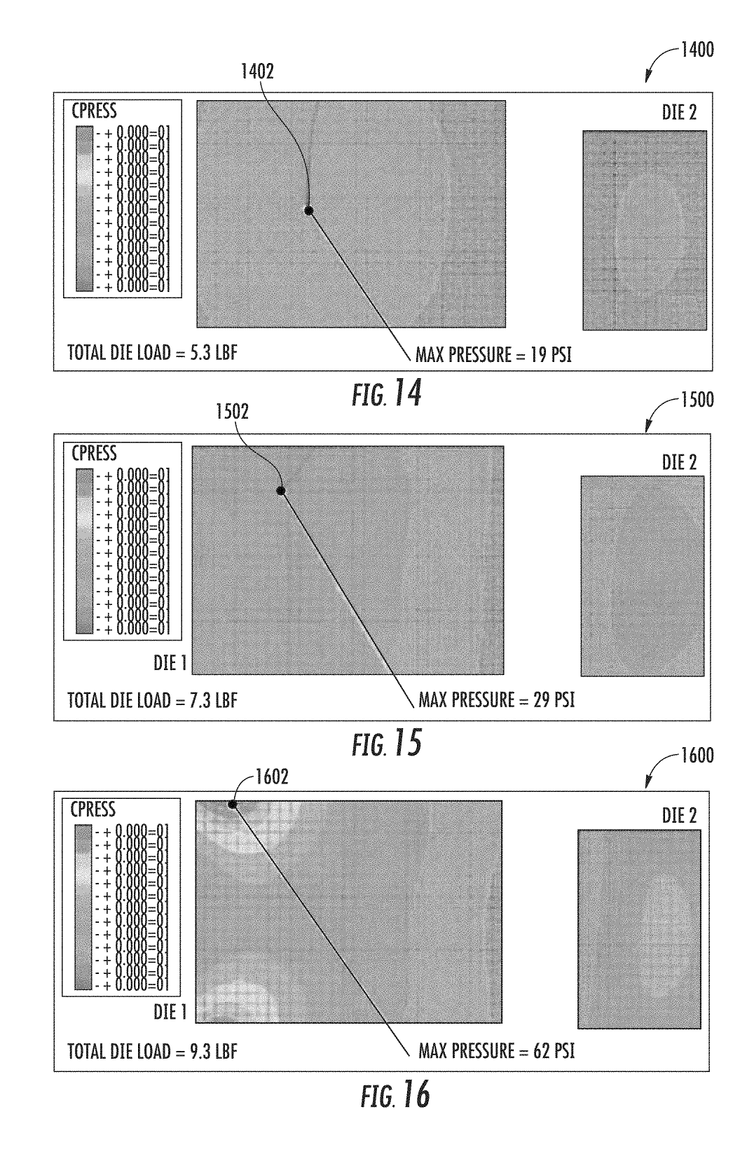

As shown in FIG. 16, a high or maximum load condition 1600 is associated with, or otherwise corresponds to, a displacement or deformation of the securing devices that is about 1.30 millimeters. In response to such deformation, the securing devices apply pressures that are greater than those applied in the medium load condition 1500, and greater loads are experienced in the high load condition 1600 than in the medium load condition 1500 as a result. A maximum pressure 1602 of about 62 psi is applied by the securing devices in the high load condition 1600, and a total die load of about 9.3 lbf is experienced as a result.

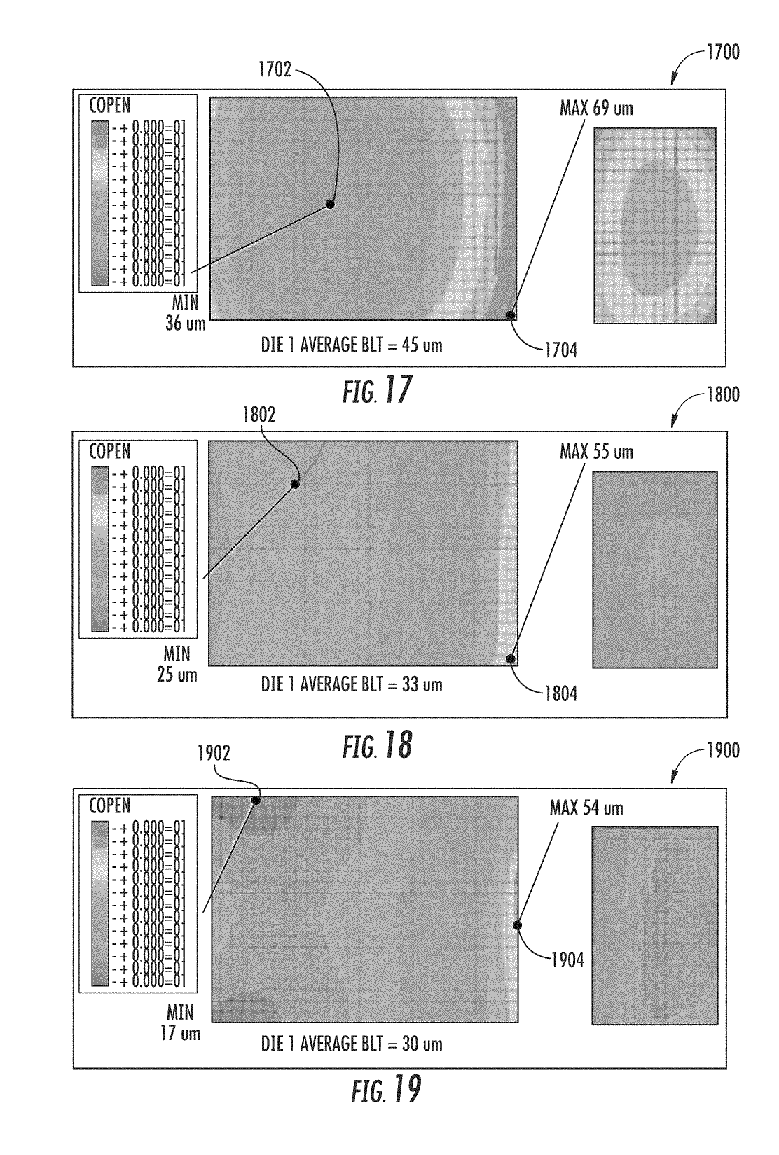

Referring now to FIGS. 17-19, bond line thicknesses of conductive material when the securing devices are employed in a fashion similar to the illustrative devices 108A, 108B are depicted during several conditions. The assumptions described above with reference to FIGS. 14-16 apply with equal force to FIGS. 17-19.

In response to the pressures applied by the securing devices during the low load condition 1400, the bond line thicknesses of the conductive material vary according to the bond line thickness map 1700 shown in FIG. 17. The bond line thickness map 1700 includes a point 1702 and a point 1704. The point 1702 is associated with, or otherwise corresponds to, a minimum bond line thickness of about 36 micrometers. The point 1704 is associated with, or otherwise corresponds to, a maximum bond line thickness of about 69 micrometers. The average bond line thickness indicated by the bond line thickness map 1700 is about 45 micrometers.

In response to the pressures applied by the securing devices during the medium load condition 1500, the bond line thicknesses of the conductive material vary according to the bond line thickness map 1800 shown in FIG. 18. The bond line thickness map 1800 includes a point 1802 and a point 1804. The point 1802 is associated with, or otherwise corresponds to, a minimum bond line thickness of about 25 micrometers. The point 1804 is associated with, or otherwise corresponds to, a maximum bond line thickness of about 55 micrometers. The average bond line thickness indicated by the bond line thickness map 1800 is about 33 micrometers.

In response to the pressures applied by the securing devices during the high load condition 1600, the bond line thicknesses of the conductive material vary according to the bond line thickness map 1900 shown in FIG. 19. The bond line thickness map 1900 includes a point 1902 and a point 1904. The point 1902 is associated with, or otherwise corresponds to, a minimum bond line thickness of about 17 micrometers. The point 1904 is associated with, or otherwise corresponds to, a maximum bond line thickness of about 54 micrometers. The average bond line thickness indicated by the bond line thickness map 1900 is about 30 micrometers.

Referring now to FIGS. 14-19, across the low, medium, and high load conditions 1400, 1500, 1600 discussed above, the largest variation between the corresponding maximum pressures 1402, 1502, 1602 is about 43 psi. Additionally, the largest variation between the average bond thicknesses indicated by the bond thickness maps 1700, 1800, 1900, which correspond to the low, medium, and high load conditions 1400, 1500, 1600 discussed above, is 15 micrometers.

### EXAMPLES

Illustrative examples of the technologies disclosed herein are provided below. An embodiment of the technologies may include any one or more, and any combination of, the examples described below.

Example 1 includes a thermal exchanger securing device to secure a thermal exchanger to an integrated circuit package, the thermal exchanger securing device comprising a main body formed from a super-elastic material and formed to couple with the thermal exchanger; and a plurality of elastic deformers formed from the super-elastic material, wherein each of the plurality of elastic deformers extends from the main body and comprises a mounting aperture, and wherein each elastic deformer is moveable from an un-deformed position to a deformed position to facilitate securement of the thermal exchanger securing device via the corresponding mounting aperture.

Example 2 includes the subject matter of Example 1, and wherein each elastic deformer is formed to elastically deform such that movement of each elastic deformer from the deformed position to the un-deformed position is facilitated when the thermal exchanger securing device is unsecured via the corresponding mounting aperture.

Example 3 includes the subject matter of any of Examples 1 and 2, and wherein the main body and the plurality of elastic deformers are formed from Nickel-Titanium.

Example 4 includes the subject matter of any of Examples 1-3, and wherein when each elastic deformer is in the un-deformed position, each elastic deformer extends outwardly from the main body at an obtuse angle measured from the main body.

Example 5 includes the subject matter of any of Examples 1-4, and wherein the obtuse angle is about 203.6°.

Example 6 includes the subject matter of any of Examples 1-5, and further including a pair of necks each coupled between a corresponding elastic deformer and the main body, wherein each of the pair of necks has a first width that is less than a second width of the main body.

Example 7 includes the subject matter of any of Examples 1-6, and wherein the first width is about 2.10 millimeters and the second width is about 5 millimeters.

Example 8 includes the subject matter of any of Examples 1-7, and wherein each of the elastic deformers has a third width that is equal to the second width.

Example 9 includes the subject matter of any of Examples 1-8, and further including a pair of neck-body transition segments each interconnecting a corresponding neck with the main body, and a pair of neck-deformer transition segments each interconnecting a corresponding neck with a corresponding elastic deformer.

Example 10 includes the subject matter of any of Examples 1-9, and wherein each neck-body transition segment has a third width that is greater than the first width and less than the second width.

Example 11 includes the subject matter of any of Examples 1-10, and wherein each neck-deformer transition segment has a fourth width that is greater than the first width and less than the second width.

Example 12 includes the subject matter of any of Examples 1-11, and wherein the plurality of elastic deformers comprises two elastic deformers.

Example 13 includes the subject matter of any of Examples 1-12, and wherein the main body and each elastic deformer has a thickness of about 0.60 millimeters.

Example 14 includes the subject matter of any of Examples 1-13, and wherein when each elastic deformer is in the un-deformed position, the thermal exchanger securing device has a length of about 65.87 millimeters.

Example 15 includes the subject matter of any of Examples 1-14, and wherein when each elastic deformer is in the deformed position, the thermal exchanger securing device has a length of about 68.99 millimeters.

Example 16 includes the subject matter of any of Examples 1-15, and wherein when each elastic deformer is in the un-deformed position, the thermal exchanger securing device has a height in the range of about 8.67 millimeters to 9.47 millimeters.

Example 17 includes the subject matter of any of Examples 1-16, and wherein the thermal exchanger securing device has a stiffness of about 0.08 N/mm

Example 18 includes a compute device comprising a printed circuit board; and a compute resource coupled to the printed circuit board, wherein the compute resource includes (i) an integrated circuit package, (ii) a thermal exchanger coupled to the integrated circuit package to dissipate heat generated during operation of the integrated circuit package, and (iii) a thermal exchanger securing device to secure the thermal exchanger and the integrated circuit package to the printed circuit board, and wherein the thermal exchanger securing device is formed from a super-elastic material and comprises a plurality of elastic deformers moveable from an un-deformed position to a deformed position to facilitate securement of the thermal exchanger securing device to the printed circuit board.

Example 19 includes the subject matter of Example 18, and wherein each of the elastic deformers comprises a mounting aperture, and wherein the mounting aperture facilitates securement of the thermal exchanger securing device to the printed circuit board when each of the elastic deformers is in the deformed position.

Example 20 includes the subject matter of any of Examples 18 and 19, and wherein each elastic deformer is formed to elastically deform such that movement of each elastic deformer from the deformed position to the un-deformed position is facilitated when the thermal exchanger securing device is unsecured to the printed circuit board.

Example 21 includes the subject matter of any of Examples 18-20, and wherein the thermal exchanger securing device is formed from Nickel-Titanium.

Example 22 includes the subject matter of any of Examples 18-21, and wherein the thermal exchanger securing device further comprises a main body to couple with the thermal exchanger, and wherein each of the elastic deformers extends from the main body.

Example 23 includes the subject matter of any of Examples 18-22, and wherein when each elastic deformer is in the un-deformed position, each elastic deformer extends outwardly from the main body at an obtuse angle measured from the main body.

Example 24 includes the subject matter of any of Examples 18-23, and wherein the thermal exchanger securing device further comprises a pair of necks each coupled between a corresponding elastic deformer and the main body, and wherein each of the pair of necks has a first width that is less than a second width of the main body.

Example 25 includes the subject matter of any of Examples 18-24, and wherein the thermal exchanger securing device further comprises (i) a pair of neck-body transition segments each interconnecting a corresponding neck with the main body and (ii) a pair of neck-deformer transition segments each interconnecting a corresponding neck with a corresponding elastic deformer.

Example 26 includes the subject matter of any of Examples 18-25, and wherein each neck-body transition segment has a third width that is greater than the first width and less than the second width, and wherein each neck-deformer transition segment has a fourth width that is greater than the first width and less than the second width.

Example 27 includes the subject matter of any of Examples 18-26, and wherein the plurality of elastic deformers comprises two elastic deformers.

Example 28 includes the subject matter of any of Examples 18-27, and further including a second thermal exchanger securing device to secure the thermal exchanger and the integrated circuit package to the printed circuit board, wherein the second thermal exchanger securing device is formed from a super-elastic material and comprises a second plurality of elastic deformers moveable from an un-deformed position to a deformed position to facilitate securement of the second thermal exchanger securing device to the printed circuit board.

Example 29 includes a compute device comprising a printed circuit board; and a compute resource coupled to the printed circuit board, wherein the compute resource includes (i) an integrated circuit package, (ii) a thermal exchanger coupled to the integrated circuit package to dissipate heat generated during operation of the integrated circuit package, and (iii) a thermal exchanger securing device to secure the thermal exchanger and the integrated circuit package to the printed circuit board, and wherein the thermal exchanger securing device is formed from a super-elastic material and comprises (a) a main body that has a first width, (b) a pair of elastic deformers that each have a second width equal to the first width and are each moveable from an un-deformed position to a deformed position to facilitate securement of the thermal exchanger securing device to the printed circuit board, and (c) a pair of necks that each have a third width less than the first width and are each coupled between the main body and a corresponding elastic deformer.

Example 30 includes the subject matter of Example 29, and wherein each of the elastic deformers comprises a mounting aperture, and wherein the mounting aperture facilitates securement of the thermal exchanger securing device to the printed circuit board when each of the elastic deformers is in the deformed position.

Example 31 includes the subject matter of any of Examples 29 and 30, and wherein each elastic deformer is formed to elastically deform such that movement of each elastic deformer from the deformed position to the un-deformed position is facilitated when the thermal exchanger securing device is unsecured to the printed circuit board.

Example 32 includes the subject matter of any of Examples 29-31, and wherein the thermal exchanger securing device is formed from Nickel-Titanium.

Example 33 includes the subject matter of any of Examples 29-32, and wherein when each elastic deformer is in the un-deformed position, each elastic deformer extends outwardly from the main body at an obtuse angle measured from the main body.

Example 34 includes the subject matter of any of Examples 29-33, and wherein the thermal exchanger securing device further comprises (i) a pair of neck-body transition segments each interconnecting a corresponding neck with the main body and (ii) a pair of neck-deformer transition segments each interconnecting a corresponding neck with a corresponding elastic deformer.

Example 35 includes the subject matter of any of Examples 29-34, and wherein each neck-body transition segment has a fourth width that is greater than the third width and less than the first width, and wherein each neck-deformer transition segment has a fifth width that is greater than the third width and less than the first width.

Example 36 includes the subject matter of any of Examples 29-35, and further including a second thermal exchanger securing device to secure the thermal exchanger and the integrated circuit package to the printed circuit board, wherein the second thermal exchanger securing device is formed from a super-elastic material and comprises a second pair of elastic deformers each moveable from an un-deformed position to a deformed position to facilitate securement of the second thermal exchanger securing device to the printed circuit board.

Example 37 includes a method of mounting a compute resource to a printed circuit board, the method comprising arranging the compute resource on the printed circuit board, applying a thermal interface material of the compute resource to an integrated circuit package of the compute resource, mounting a thermal exchanger of the compute resource onto the integrated circuit package, and securing the compute resource to the printed circuit board, wherein securing the compute resource to the printed circuit board includes (i) coupling a thermal exchanger securing device of the compute resource to the thermal exchanger such that a main body of the thermal exchanger securing device is coupled to the thermal exchanger and elastic deformers of the thermal exchanger securing device that are formed from a super-elastic material extend outwardly from the main body away from the printed circuit board in un-deformed positions and (ii) securing the thermal exchanger securing device to the printed circuit board by deforming the elastic deformers from the un-deformed positions to deformed positions and attaching the elastic deformers to the printed circuit board.

Example 38 includes the subject matter of Example 37, and wherein securing the thermal exchanger securing device to the printed circuit board comprises bending the elastic deformers relative to the main body to cause the elastic deformers to move from the un-deformed positions to the deformed positions.

Example 39 includes the subject matter of any of Examples 37 and 38, and wherein bending the elastic deformers relative to the main body comprises moving a plurality of necks of the thermal exchanger securing device from un-flexed positions to flexed positions.

Example 40 includes the subject matter of any of Examples 37-39, and wherein coupling the thermal exchanger securing device to the thermal exchanger comprises coupling the main body to the thermal exchanger such that the elastic deformers extend at obtuse angles measured from the main body in the un-deformed positions.

Example 41 includes a thermal exchanger securing device comprising a main body formed from a super-elastic material; and a plurality of elastic deformers formed from the super-elastic material, wherein each of the plurality of elastic deformers extends from the main body, and wherein each elastic deformer is moveable from an un-deformed position to a deformed position in response to forces applied to each elastic deformer.

Example 42 includes the subject matter of Example 41, and wherein each elastic deformer is formed to elastically deform such that movement of each elastic deformer from the deformed position to the un-deformed position is facilitated when the forces are removed.

Example 43 includes the subject matter of any of Examples 41 and 42, and wherein the main body and the plurality of elastic deformers are formed from a shape-memory alloy.

Example 44 includes the subject matter of any of Examples 41-43, and wherein the plurality of elastic deformers comprises two elastic deformers.

Example 45 includes the subject matter of any of Examples 41-44, and wherein the thermal exchanger securing device comprises a spring.

Example 46 includes the subject matter of any of Examples 41-45, and wherein the thermal exchanger securing device comprises a leaf spring.

Example 47 includes the subject matter of any of Examples 41-46, and wherein the thermal exchanger securing device comprises a coil spring.

Example 48 includes the subject matter of any of Examples 41-47, and wherein the thermal exchanger securing device comprises a torsion bar.

Example 49 includes the subject matter of any of Examples 41-48, and wherein the thermal exchanger securing device comprises a load frame.

Example 50 includes the subject matter of any of Examples 41-49, and wherein each of the plurality of elastic deformers extends generally parallel to the main body when each of the plurality of elastic deformers is in the deformed position.

1. A thermal exchanger securing device to secure a thermal exchanger to an integrated circuit package, the thermal exchanger securing device comprising:
a main body formed from a super-elastic material and formed to couple with the thermal exchanger; and
a plurality of elastic deformers formed from the super-elastic material, wherein each of the plurality of elastic deformers extends from the main body and comprises a mounting aperture, and wherein each elastic deformer is moveable from an un-deformed position to a deformed position to facilitate securement of the thermal exchanger securing device via the corresponding mounting aperture.

2. The thermal exchanger securing device of claim 1, wherein each elastic deformer is formed to elastically deform such that movement of each elastic deformer from the deformed position to the un-deformed position is facilitated when the thermal exchanger securing device is unsecured via the corresponding mounting aperture, and wherein the main body and the plurality of elastic deformers are formed from Nickel-Titanium.

3. The thermal exchanger securing device of claim 1, wherein when each elastic deformer is in the un-deformed position, each elastic deformer extends outwardly from the main body at an obtuse angle of about 203.6° measured from the main body.

4. The thermal exchanger securing device of claim 1, further comprising:
a pair of necks each coupled between a corresponding elastic deformer and the main body, wherein each of the pair of necks has a first width of about 2.10 millimeters, and wherein the main body has a second width of about 5 millimeters.

5. The thermal exchanger securing device of claim 4, wherein each of the elastic deformers has a third width that is equal to the second width.

6. The thermal exchanger securing device of claim 4, further comprising:
a pair of neck-body transition segments each interconnecting a corresponding neck with the main body, and
a pair of neck-deformer transition segments each interconnecting a corresponding neck with a corresponding elastic deformer,
wherein each neck-body transition segment has a third width that is greater than the first width and less than the second width.

7. The thermal exchanger securing device of claim 6, wherein each neck-deformer transition segment has a fourth width that is greater than the first width and less than the second width.

8. The thermal exchanger securing device of claim 1, wherein the plurality of elastic deformers comprises two elastic deformers, and wherein the main body and each elastic deformer has a thickness of about 0.60 millimeters.

9. The thermal exchanger securing device of claim 1, wherein when each elastic deformer is in the un-deformed position, the thermal exchanger securing device has a length of about 65.87 millimeters.

10. The thermal exchanger securing device of claim 9, wherein when each elastic deformer is in the deformed position, the thermal exchanger securing device has a length of about 68.99 millimeters.

11. The thermal exchanger securing device of claim 9, wherein when each elastic deformer is in the un-deformed position, the thermal exchanger securing device has a height in the range of about 8.67 millimeters to 9.47 millimeters.

12. The thermal exchanger securing device of claim 1, wherein the thermal exchanger securing device has a stiffness of about 0.08 N/mm.

13. A compute device comprising:
a printed circuit board; and
a compute resource coupled to the printed circuit board, wherein the compute resource includes (i) an integrated circuit package, (ii) a thermal exchanger coupled to the integrated circuit package to dissipate heat generated during operation of the integrated circuit package, and (iii) a thermal exchanger securing device to secure the thermal exchanger and the integrated circuit package to the printed circuit board, and wherein the thermal exchanger securing device is formed from a super-elastic material and comprises a plurality of elastic deformers moveable from an un-deformed position to a deformed position to facilitate securement of the thermal exchanger securing device to the printed circuit board.

14. The compute device of claim 13, wherein the thermal exchanger securing device is formed from Nickel-Titanium.

15. The compute device of claim 13, wherein the thermal exchanger securing device further comprises a main body to couple with the thermal exchanger, and wherein when each elastic deformer is in the un-deformed position, each elastic deformer extends outwardly from the main body at an obtuse angle measured from the main body.

16. The compute device of claim 15, wherein the thermal exchanger securing device further comprises a pair of necks each coupled between a corresponding elastic deformer and the main body, and wherein each of the pair of necks has a first width that is less than a second width of the main body.

17. The compute device of claim 16, wherein the thermal exchanger securing device further comprises (i) a pair of neck-body transition segments each interconnecting a corresponding neck with the main body and (ii) a pair of neck-deformer transition segments each interconnecting a corresponding neck with a corresponding elastic deformer, wherein each neck-body transition segment has a third width that is greater than the first width and less than the second width, and wherein each neck-deformer transition segment has a fourth width that is greater than the first width and less than the second width.

18. The compute device of claim 13, further comprising:
a second thermal exchanger securing device to secure the thermal exchanger and the integrated circuit package to the printed circuit board, wherein the second thermal exchanger securing device is formed from a super-elastic material and comprises a second plurality of elastic deformers moveable from an un-deformed position to a deformed position to facilitate securement of the second thermal exchanger securing device to the printed circuit board.

19. A method of mounting a compute resource to a printed circuit board, the method comprising:
arranging the compute resource on the printed circuit board,
applying a thermal interface material of the compute resource to an integrated circuit package of the compute resource,
mounting a thermal exchanger of the compute resource onto the integrated circuit package, and
securing the compute resource to the printed circuit board, wherein securing the compute resource to the printed circuit board includes (i) coupling a thermal exchanger securing device of the compute resource to the thermal exchanger such that a main body of the thermal exchanger securing device is coupled to the thermal exchanger and elastic deformers of the thermal exchanger securing device that are formed from a super-elastic material extend outwardly from the main body away from the printed circuit board in un-deformed positions and (ii) securing the thermal exchanger securing device to the printed circuit board by deforming the elastic deformers from the un-deformed positions to deformed positions and attaching the elastic deformers to the printed circuit board.

20. The method of claim 19, wherein securing the thermal exchanger securing device to the printed circuit board comprises bending the elastic deformers relative to the main body to cause the elastic deformers to move from the un-deformed positions to the deformed positions, and wherein bending the elastic deformers relative to the main body comprises moving a plurality of necks of the thermal exchanger securing device from un-flexed positions to flexed positions.

21. The method of claim 19, wherein coupling the thermal exchanger securing device to the thermal exchanger comprises coupling the main body to the thermal exchanger such that the elastic deformers extend at obtuse angles measured from the main body in the un-deformed positions.

22. A thermal exchanger securing device comprising:
a main body formed from a super-elastic material; and
a plurality of elastic deformers formed from the super-elastic material, wherein each of the plurality of elastic deformers extends from the main body, and wherein each elastic deformer is moveable from an un-deformed position to a deformed position in response to forces applied to each elastic deformer.

23. The thermal exchanger securing device of claim 22, wherein each elastic deformer is formed to elastically deform such that movement of each elastic deformer from the deformed position to the un-deformed position is facilitated when the forces are removed, and wherein the main body and the plurality of elastic deformers are formed from a shape-memory alloy.

24. The thermal exchanger securing device of claim 22, wherein the thermal exchanger securing device comprises a leaf spring, a coil spring, a torsion bar, or a load frame.

25. The thermal exchanger securing device of 22, wherein each of the plurality of elastic deformers extends generally parallel to the main body when each of the plurality of elastic deformers is in the deformed position.
